(19) United States
(12) Patent Application Publication
(10) Pub. No.: US 2025/0060675 A1
(43) Pub. Date: Feb. 20, 2025

(54) PHOTORESIST STRIPPER COMPOSITION AND METHOD FOR FORMING PATTERN USING THE SAME

(71) Applicants: Samsung Display Co., Ltd., Yongin-si (KR); LTC Co., Ltd, Hwaseong-si (KR)

(72) Inventors: KYU-SOON PARK, Yongin-si (KR); YOUNGROK KIM, Yongin-si (KR); Seonjeong KIM, Hwaseong-si (KR); Hyerim YANG, Hwaseong-si (KR); Jongsoon LEE, Hwaseong-si (KR); Byeongwoo JEON, Hwaseong-si (KR); JONG-HYUN CHOUNG, Yongin-si (KR); WOOJIN CHO, Yongin-si (KR)

(21) Appl. No.: 18/806,551

(22) Filed: Aug. 15, 2024

(30) Foreign Application Priority Data
Aug. 17, 2023 (KR) 10-2023-0107834

(51) Int. Cl. G03F 7/38; G03F 7/09; G03F 7/20; G03F 7/32

(52) U.S. Cl. CPC G03F 7/38; G03F 7/094; G03F 7/2026; G03F 7/325

(57) ABSTRACT

A photoresist stripper composition according to one or more embodiments includes an amine compound, a cyclic alcohol, a protic polar organic solvent, an aprotic polar organic solvent, and a polyhydric alcohol having 4 to 6 carbon atoms. The amine compound in the photoresist stripper composition may have a molecular weight of about 80 g/mol or less, and a HSPo value according to Equation 1 of about 27 to about 32. The photoresist stripper composition according to one or more embodiments may be utilized in a process of removing a photoresist pattern formed on a lower film, and may supply an excellent or suitable strip ability for photoresist and characteristics of preventing or reducing damage of the lower film.

### CROSS-REFERENCE TO RELATED APPLICATION

This application claims priority to and the benefit of Korean Patent Application No. 10-2023-0107834, filed on Aug. 17, 2023, the entire content of which is hereby incorporated by reference.

### BACKGROUND

One or more aspects of embodiments of the present disclosure herein are directed toward a photoresist stripper composition and a method for forming (or providing) a pattern utilizing the same, and for example, to a photoresist stripper composition for removing photoresist and a method for forming (or providing) a pattern utilizing the same.

A photolithography process utilizing photoresist may be performed in a semiconductor manufacturing process, and a panel process of a display device. For example, a photoresist pattern may be formed by forming (or providing) a photoresist layer on a substrate and exposing and developing the photoresist layer.

In the photolithography process, a photoresist stripper composition is utilized to remove the photoresist pattern. However, in related art photoresist stripper compositions, an environmentally regulated material (e.g., a material that may be deemed hazardous and/or toxic, and/or may be considered a contaminant and/or pollutant) is partially included. Accordingly, there is a need (or desire) to develop technology for the photoresist stripper composition that does not include any environmentally regulated materials and that has an excellent or suitable photoresist pattern removal property.

### SUMMARY

One or more aspects of embodiments of the present disclosure are directed toward a photoresist stripper composition capable of improving a strip ability (e.g., stripping ability) and/or a dissolution performance for a photoresist pattern, while minimizing or reducing corrosion of a film under the photoresist pattern.

One or more aspects of embodiments of the present disclosure are also directed toward a method for forming (or providing) a pattern utilizing the photoresist stripper composition described above.

One or more embodiments of the present disclosure provide a photoresist stripper composition including, with respect to a total weight of the composition, about 5% to about 15% by weight of an amine compound having a molecular weight of about 80 g/mol or less and a Hansen solubility parameter (HSPo) according to Equation 1 of about 27 to about 32, about 5% to about 15% by weight of a cyclic alcohol, about 10% to about 55% by weight of a protic polar organic solvent, about 10% to about 55% by weight of an aprotic polar organic solvent, and about 0.05% to about 1% by weight of a polyhydric alcohol having 4 to 6 carbon atoms.

$$HSPo = {( {HSPd}^{2} + {HSPp}^{2} + {HSPh}^{2} )}^{0.5} , \qquad Equation l$$

wherein in Equation 1, HSPd is a solubility parameter generated by non-polar dispersive bonding, HSPp is a solubility parameter generated by polar bonding caused (e.g., facilitated) by permanent dipoles, and HSPh is a solubility parameter generated by hydrogen bonding.

In one or more embodiments, the amine compound may be an alkanol amine compound.

In one or more embodiments, the amine compound may include at least one of monoisopropanolamine, 3-amino-1-propanol, monoethanolamine, or 2-methylaminoethanol.

In one or more embodiments, the amine compound may be a primary amine compound.

In one or more embodiments, the cyclic alcohol may have 4 to 6 carbon atoms in a molecule.

In one or more embodiments, the cyclic alcohol may include at least one of tetrahydrofurfuryl alcohol, furfuryl alcohol, cyclobutanol, cyclopentanol, cyclohexanol, or isopropylideneglycerol.

In one or more embodiments, the protic polar organic solvent may include a glycol-based compound represented by Formula 1 or Formula 2, which is described in more detail hereinbelow.

In one or more embodiments, the protic polar organic solvent may include at least one of ethyleneglycol, propyleneglycol, diethyleneglycolmonoethylether, diethyleneglycolmonobutylether, diethyleneglycolmonomethylether, ethyleneglycolmonoethylether, ethyleneglycolmonobutylether, propyleneglycolmonomethylether, propyleneglycolmonoethylether, propyleneglycolmonobutylether, diethyleneglycolmonoethylether, diethyleneglycolmonopropylether, diethyleneglycolmonobutylether, dipropyleneglycolmonomethylether, dipropyleneglycolmonoethylether, dipropyleneglycolmonopropylether, dipropyleneglycolmonobutylether, triethyleneglycolmonopropylether, triethyleneglycolmonobutylether, triethyleneglycolmonomethylether, tripropyleneglycolmonoethylether, tripropyleneglycolmonopropylether, or tripropyleneglycolmonobutylether.

In one or more embodiments, the photoresist stripper composition may not include (e.g., may exclude)N-methyl-2-pyrrolidone and/or N-methylformamide.

In one or more embodiments, the aprotic polar organic solvent may include at least one of 2-pyrrolidone, 4-formylmorpholine, N,N-dimethylpropionamide, 1,3-dimethyl-2-imidazolidinone, N,N-dimethylacetoacetamide, sulfolane, N-ethylformamide, or equamide (3-methoxy-N,N-dimethylpropanamide).

Ione or more embodiments, the polyhydric alcohol may be a linear alkyl alcohol.

In one or more embodiments, the polyhydric alcohol may include at least one of erythritol, threitol, arabitol, xylitol, ribitol, mannitol, sorbitol, galactitol, fucitol, or iditol.

In one or more embodiments, the photoresist stripper composition may not include (e.g., may exclude) water.

In one or more embodiments, the photoresist stripper composition may have a specific gravity of about 1.01 or more.

In one or more embodiments of the present disclosure, a method for forming (or providing) a pattern includes forming (or providing) a photoresist pattern on a substrate on which a lower film is formed, forming (or providing) a wiring pattern using (e.g., utilizing) the photoresist pattern, and removing the photoresist pattern by (e.g., by supplying) a photoresist stripper composition. The photoresist stripper composition according to the present embodiments may be utilized as the photoresist stripper composition in the removing of the photoresist pattern.

In one or more embodiments, the lower film may include a metal film selected from among aluminum (Al), copper (Cu), and an alloy thereof; a metal oxide film such as a silicon oxide film and/or a silicon nitride film; and/or any suitable combination thereof.

In one or more embodiments, the lower film may be a single-layered film or a multi-layered film.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a flowchart illustrating a method for forming (or providing) a pattern according to one or more embodiments;

FIGS. 2-6 are each a cross-sectional view schematically illustrating a method for forming (or providing) a pattern, respectively; and

FIG. 7 shows scanning electron micrographs of lower films to which photoresist stripper compositions according to some of Examples and some of Comparative Examples are respectively supplied.

### DETAILED DESCRIPTION

In the present disclosure, one or more suitable modifications may be made and one or more suitable forms may be applied, and example embodiments will be illustrated in the drawings and described in more detail in the text. However, this is not intended to limit the present disclosure to a specific disclosure form, rather, it should be understood to include all changes, equivalents, and substitutes included within the spirit and scope of the present disclosure.

In describing each drawing, similar reference numerals have been utilized for similar elements. In the accompanying drawings, the dimensions of the structures are shown to be enlarged (e.g., larger than actual) for clarity of the present disclosure. Terms such as first and second may be utilized to describe one or more suitable components, but the components should not be limited by the terms. These terms are utilized only for the purpose of distinguishing one component from another component. For example, without departing from the scope of the present disclosure, a first component may be referred to as a second component, and similarly, a second component may be referred to as a first component. Singular expressions include plural expressions unless the context clearly indicates otherwise.

In the present application, terms such as “comprise” and/or “have” are intended to designate the presence of features, numbers, steps, actions, components, parts, or combinations thereof described in the specification. It should be understood that the possibility of the presence or addition of one or more other features or numbers, steps, actions, components, parts, or combinations thereof is not excluded in advance.

In the present application, if (e.g., when) a part of a layer, film, region, plate, and/or the like is said to be “on” or “above” another part, it includes not only “directly on” or “directly above” another part (e.g., without any intervening parts therebetween), but also one or more other parts being present in the middle (e.g., therebetween). Conversely, if (e.g., when) a part such as a layer, film, region, and/or plate is said to be “under” or “below” another part, this includes not only the case where the other part is “directly under” or “directly below” (e.g., without any intervening parts therebetween), but also the case where there one or more other parts are present in the middle (e.g., therebetween). In one or more embodiments, in the present application, the term “above” may include a case where the element is arranged not only at the top but also at the bottom.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

In present disclosure and unless otherwise defined, “not including a or any ‘component” “excluding a or any ‘component’”, “‘component’-free”, and/or the like refers to that the “component” not being added, selected or utilized as a component in the formula/composition/structure, but the “component” of less than a suitable amount may still be included due to other impurities and/or external factors.

Hereinafter, a photoresist stripper composition according to one or more embodiments of the present disclosure will be described.

The photoresist stripper composition according to one or more embodiments may be utilized to strip (e.g., dissolve) a photoresist pattern formed on a lower film. The photoresist stripper composition according to one or more embodiments may be utilized to strip the photoresist pattern formed on a metal film and/or a metal oxide film.

In one or more embodiments, the photoresist stripper composition according to one or more embodiments may be utilized to strip the photoresist pattern formed on the lower film, which may be a combination of the metal film and the metal oxide film. The lower film under the photoresist pattern may include the metal film, the metal oxide film, and/or any suitable combination thereof, and may be a single-layered film or a multi-layered film.

The photoresist stripper composition according to one or more embodiments of the present disclosure may include an amine compound, a cyclic alcohol, a protic polar organic solvent, an aprotic polar organic solvent, and a polyhydric alcohol.

The amine compound included in the photoresist stripper composition according to one or more embodiments may serve to weaken a binding force of the photoresist pattern. For example, the amine compound may break down and/or cut a molecular bonding in a cured photoresist resin. Accordingly, the photoresist stripper composition including the amine compound may show characteristics of facilitating removal of the photoresist pattern.

In one or more embodiments, the amine compound may have a relatively small molecular weight so as to increase a strip rate of the photoresist pattern, and may have a Hansen solubility parameter value of about 27 to about 32. The molecular weight may be a weight average molecular weight. The amine compound has a relatively low molecular weight, and the Hansen solubility parameter value in a range described above, and thus a dissolution ability and the strip rate of the photoresist pattern may be increased.

For example, the amine compound may have a molecular weight of about 80 g/mol or less. In one or more embodiments, the amine compound may have a molecular weight of about 30 g/mol to about 80 g/mol. When the amine compound included in the photoresist stripper composition according to one or more embodiments is about 80 g/mol or less, the strip rate may be increased. The amine compound included in the photoresist stripper composition according to one or more embodiments is about 80 g/mol or less, and within the molecular weight range according to the present embodiments, the smaller molecular weight, the shorter strip time of the photoresist pattern.

In one or more embodiments, the amine compound may have the Hansen solubility parameter according to Equation 1 of about 27 to about 32. The amine compound of which the Hansen solubility parameter according to Equation 1 satisfies the range described above may increase the dissolution ability for the photoresist pattern. Accordingly, the photoresist stripper composition including the amine compound according to one or more embodiments may increase the strip rate.

$$HSPo = {( {HSPd}^{2} + {HSPp}^{2} + {HSPh}^{2} )}^{0.5} \qquad Equation l$$

In Equation 1, HSPd may be a solubility parameter generated by non-polar dispersive bonding. HSPp may be a solubility parameter generated by polar bonding caused by permanent dipoles. HSPh may be a solubility parameter generated by hydrogen bonding.

In one or more embodiments, if (e.g., when) the Hansen solubility parameter (HSPo) according to Equation 1 is about 27 to about 32, and the higher it is within this range, the amine compound may increase the strip rate.

According to one or more embodiments, the amine compound may include at least one hydroxy group. For example, the amine compound may be an alkanol amine compound including one hydroxy group. In the alkanol amine compound, the hydroxy group may be placed in an end (e.g., at a terminal end) and/or on a side chain of the amine compound. The alkanol amine compound may have a molecular weight of about 80 g/mol or less, and the HSPo according to Equation 1 of about 27 to about 32.

As long as the amine compound suitably satisfies the molecular weight range described above and the range of the Hansen solubility parameter value according to Equation 1, a type or kind of the amine compound may not be specially limited. For example, the amine compound may include at least one of monoisopropanolamine, 3-amino-1-propanol, monoethanolamine, or 2-methylaminoethanol. These may be utilized alone or in combination of two or more.

The amine compound included in the photoresist stripper composition according to one or more embodiments may be a primary amine compound. For example, the photoresist stripper composition may include at least one of monoisopropanolamine, 3-amino-1-propanol, or monoethanolamine, but one or more embodiments of the present disclosure is not limited thereto.

In one or more embodiments, the amine compound may have a content (e.g., amount) of about 5% to about 15% by weight with respect to the total weight of the photoresist stripper composition. When the amine compound has a content (e.g., amount) of less than about 5% by weight, it may be difficult to sufficiently or suitably demonstrate a strip performance of (e.g., may be difficult to sufficiently or suitably dissolve) the photoresist stripper composition. In one or more embodiments, when the amine compound has a content (e.g., amount) of more than about 15% by weight, the lower film under the photoresist pattern may be damaged.

The photoresist stripper composition according to one or more embodiments of the present disclosure may include the cyclic alcohol. The cyclic alcohol may serve to suitably maintain the performance of the photoresist stripper composition for a relatively long time by reducing a volatilization amount of the photoresist stripper composition and controlling evaporation of the amine compound such as the alkanol amine.

In one or more embodiments, the cyclic alcohol may have 4 to 6 carbon atoms in a molecule. The cyclic alcohol may include a hydrocarbon ring and/or a heterocycle having 4 to 6 carbon atoms in a molecule. The hydrocarbon ring and the heterocycle may each independently be monocyclic or polycyclic. The hydrocarbon ring includes an aliphatic hydrocarbon ring and/or an aromatic hydrocarbon ring. The heterocycle includes an aliphatic heterocycle and/or an aromatic heterocycle. The heterocycle may include at least one hetero atom such as an oxygen atom. When the heterocycle includes two or more hetero atoms, the two or more hetero atoms may be the same as, or different from each other. For example, the cyclic alcohol may include the heterocycle including one or two oxygen atoms as the hetero atoms.

In one or more embodiments, the cyclic alcohol may have an aliphatic hydrocarbon ring and/or an aromatic hydrocarbon ring having 4 to 6 carbon atoms in a molecule, and/or a heterocycle including at least one hetero atom as a ring-forming atom. In one or more embodiments, the cyclic alcohol may include one hydroxy group. For example, the cyclic alcohol may be a monohydric alcohol including one hydroxy group.

For example, the cyclic alcohol may include at least one selected from among tetrahydrofurfurylalcohol, furfurylalcohol, cyclobutanol, cyclopentanol, cyclohexanol, and isopropylideneglycerol, but one or more embodiments of the present disclosure are not limited thereto.

In one or more embodiments, the cyclic alcohol may have a content (e.g., may be in amount) of about 5% to about 15% by weight with respect to the total weight of the photoresist stripper composition. When the cyclic alcohol has a content (e.g., amount) of less than about 5% by weight, it may be difficult to suitably control evaporation of the amine compound, and thus the strip performance of the photoresist stripper composition may not be sufficiently or suitably demonstrated. In one or more embodiments, if (e.g., when) the cyclic alcohol has a content (e.g., amount) of more than about 15% by weight, the lower film under the photoresist pattern may be damaged.

The photoresist stripper composition according to one or more embodiments of the present disclosure may include a protic polar organic solvent. The protic polar organic solvent may play an auxiliary role in stripping the photoresist pattern, and may disperse a dissolved photoresist material in the photoresist stripper composition.

The protic polar organic solvent may include a glycol-based compound. The protic polar organic solvent may include one or two types (kinds) of the glycol-based compound. The glycol-based compound may spread the dissolved photoresist in the photoresist stripper composition to help to quickly or suitably remove the same.

In this specification, a “substituted or unsubstituted” material may refer to a material that is unsubstituted or that is unsubstituted with one or more substituents selected from the group consisting of a deuterium atom, a halogen atom, a cyano group, a nitro group, an amino group, a silyl group, a hydroxy group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, a heterocyclic group, and any suitable combination thereof. In one or more embodiments, the substituent exemplified above may itself be each substituted or unsubstituted. For example, a biphenyl group may be understood as the aryl group, or a phenyl group substituted with a phenyl group.

In this specification, the alkyl group may be straight-chained or branched. The alkyl group may have 1 to 50, 1 to 30, 1 to 20, 1 to 10, or 1 to 6 carbon atoms. Examples of the alkyl group may be a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldodecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the present disclosure is not limited thereto.

In this specification, a cycloalkyl group may refer to a ring-type or kind (e.g., cyclic) alkyl group. The cycloalkyl group may have 3 to 50, 3 to 30, 3 to 20, or 3 to 10 carbon atoms. Examples of the cycloalkyl group may be a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the present disclosure is not limited thereto.

In this specification, an alkenyl group refers to a hydrocarbon group including at least one carbon double bond in the middle and/or an end of an alkyl group having two or more carbon atoms. The alkenyl group may be straight-chained or branched. A number of carbon atoms of the alkenyl group is not specially limited, but may be 2 to 30, 2 to 20, or 2 to 10. Examples of the alkenyl group may be a vinyl group, a 1-butenyl group, a 1-pentenyl group, a 1,3-butadienyl aryl group, a styrenyl group, a styrylvinyl group, and/or the like, but the present disclosure is not limited thereto.

In this specification, an alkynyl group refers to a hydrocarbon group including at least one carbon triple bond in the middle and/or an end of an alkyl group having two or more carbon atoms. The alkynyl group may be straight-chained or branched. A number of carbon atoms of the alkynyl group is not specially limited, but may be 2 to 30, 2 to 20, or 2 to 10. Examples of the alkynyl group may be an ethynyl group, a propynyl group, and/or the like, but the present disclosure is not limited thereto.

In this specification, a hydrocarbon ring group refers to a functional group (e.g., an arbitrary functional group) and/or substituent derived from an aliphatic hydrocarbon ring. The hydrocarbon ring group may be a saturated hydrocarbon ring group having 3 to 20, or 3 to 15 ring-forming carbon atoms.

In this specification, an aryl group refers to a functional group (e.g., an arbitrary functional group) and/or substituent derived from an aromatic hydrocarbon ring. The aryl group may be a monocyclic aryl group or a polycyclic aryl group. The aryl group may have 6 to 30, 6 to 20, or 6 to 15 ring-forming carbon atoms. An example of the aryl group may be a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the present disclosure is not limited thereto.

In this specification, an alkoxy group may be straight-chained or branched. A number of carbon atoms of the alkoxy group is not specially limited, but may be, for example, 1 to 20, or 1 to 10. Examples of the alkoxy group may be a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, and/or the like, but the present disclosure is not limited thereto.

In one or more embodiments, the glycol-based compound may be represented as Formula 1 or Formula 2.

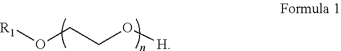

In Formula 1, R₁ may be a hydrogen atom, a substituted or unsubstituted alkyl group having 1 to 10 carbon atoms, a substituted or unsubstituted cycloalkyl group having 3 to 15 ring-forming carbon atoms, or a substituted or unsubstituted aryl group having 3 to 15 ring-forming carbon atoms. In one or more embodiments, R₁ may be a hydrogen atom, or a substituted or unsubstituted alkyl group having 1 to 10 carbon atoms. For example, R₁ may be a hydrogen atom, an unsubstituted methyl group, an unsubstituted ethyl group, an unsubstituted propyl group, an unsubstituted butyl group, and/or the like.

In Formula 1, n may be an integer of 1 or more. For example, n may be integer of 1 to 10, but one or more embodiments of the present disclosure are not limited thereto.

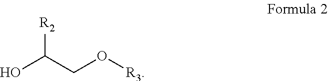

In Formula 2, R₂ may be a hydrogen atom, or a substituted or unsubstituted alkyl group having 1 to 10 carbon atoms. For example, R₂ may be a hydrogen atom or an unsubstituted methyl group, but the present disclosure is not limited thereto.

In Formula 2, R₃ may be a hydrogen atom, a substituted or unsubstituted alkyl group having 1 to 10 carbon atoms, or a substituted or unsubstituted alkoxy group having 1 to 10 carbon atoms. For example, R₃ may be a hydrogen atom, a substituted or unsubstituted methyl group, a substituted or unsubstituted ethyl group, a substituted or unsubstituted propyl group, a substituted or unsubstituted butyl group, a substituted or unsubstituted ethoxy group, and/or the like. In one or more embodiments, if (e.g., when) R₃ is substituted with another substituent, R₃ may be substituted with a hydroxy group, an alkoxy group, and/or the like, but one or more embodiments of the present disclosure are not limited thereto.

For example, the protic polar organic solvent may include at least one of ethyleneglycol, propyleneglycol, diethyleneglycolmonoethylether, diethyleneglycolmonobutylether, diethyleneglycolmonomethylether, ethyleneglycolmonoethylether, ethyleneglycolmonobutylether, propyleneglycolmonomethylether, propyleneglycolmonoethylether, propyleneglycolmonobutylether, diethyleneglycolmonoethylether, diethyleneglycolmonopropylether, diethyleneglycolmonobutylether, dipropyleneglycolmonomethylether, dipropyleneglycolmonoethylether, dipropyleneglycolmonopropylether, dipropyleneglycolmonobutylether, triethyleneglycolmonopropylether, triethyleneglycolmonobutylether, triethyleneglycolmonomethylether, tripropyleneglycolmonoethylether, tripropyleneglycolmonopropylether, or tripropyleneglycolmonobutylether. The above examples may be utilized alone or in combination of two or more thereof. The photoresist stripper composition according to one or more embodiments may include diethyleneglycolmonoethylether as the protic polar organic solvent, but one or more embodiments of the present disclosure are not limited thereto.

In one or more embodiments, the protic polar organic solvent may have a content (e.g., amount) of about 10% to about 55% by weight with respect to the total weight of the photoresist stripper composition. In one or more embodiments, the protic polar organic solvent may have a content (e.g., may be included in an amount) of about 30% to about 55% by weight, or about 30% to about 50% by weight. When the protic polar organic solvent is included in the content (e.g., amount) range described above in the photoresist stripper composition, the photoresist stripper composition may secure sufficient or suitable swelling and/or dissolution ability for the photoresist pattern. In one or more embodiments, if (e.g., when) a content (e.g., amount) of the protic polar organic solvent is less than about 10% by weight, the photoresist stripper composition may not have a sufficient or suitable dissolution ability for the photoresist pattern. In one or more embodiments, if (e.g., when) the content (e.g., amount) of the protic polar organic solvent is more than about 55% by weight, a strip performance of the photoresist stripper composition may be deteriorated, and a cost for manufacturing the photoresist stripper composition may increase.

The photoresist stripper composition according to one or more embodiments may include an aprotic polar organic solvent. The aprotic polar organic solvent may weaken or reduce a binding force of a polymer material in the photoresist to facilitate removal of the photoresist pattern modified by curing. Accordingly, the aprotic polar organic solvent may serve to maximize or increase an excellent or suitable strip ability and an excellent or suitable cleaning ability of the photoresist stripper composition according to one or more embodiments.

The aprotic polar organic solvent is not specially limited and any suitable aprotic polar organic solvent may be utilized, as long as it can suitably exclude a harmful material and has a suitable dissolution ability for the photoresist pattern. For example, the aprotic polar organic solvent may not include (e.g., may exclude)N-methyl-2-pyrrolidinone, and/or N-methylformamide, which are harmful to environment and human body. For example, the photoresist stripper composition according to one or more embodiments may improve dissolution performance for the photoresist pattern without utilizing N-methyl-2-pyrrolidinone, and/or N-methylformamide, which are harmful materials.

For example, the aprotic polar organic solvent may include at least one of 2-pyrrolidone, 4-formylmorpholine, N,N-dimethylpropionamide, 1,3-dimethyl-2-imidazolidinone, N,N-dimethylacetoacetamide, sulfolane, N-ethylformamide, or equamide. These may be utilized alone or in combination of at least two thereof. The photoresist stripper composition according to one or more embodiments may include N,N-dimethylpropionamide as the aprotic polar organic solvent, but one or more embodiments of the present disclosure are not limited thereto.

In one or more embodiments, the aprotic polar organic solvent may have a content (e.g., amount) of about 10% to about 55% by weight with respect to the total weight of the photoresist stripper composition. In one or more embodiments, the aprotic polar organic solvent may have a content (e.g., amount) of about 30% to about 55% by weight, or about 30% to about 50% by weight. When the aprotic polar organic solvent is included in the content (e.g., amount) range described above in the photoresist stripper composition, an excellent or suitable strip ability for the photoresist that has been cured and/or modified may be obtained, and a dissolution ability for the stripped photoresist may be maximized or increased. In one or more embodiments, if (e.g., when) the content (e.g., amount) of the aprotic polar organic solvent is less than about 10% by weight, removal ability of the modified photoresist may not be suitable or sufficient. In one or more embodiments, if (e.g., when) the content (e.g., amount) of the aprotic polar organic solvent is more than about 55% by weight, the strip performance of the photoresist stripper composition may be deteriorated, and a cost for manufacturing the photoresist stripper composition may increase.

The photoresist stripper composition according to one or more embodiments may include the polyhydric alcohol. The polyhydric alcohol may improve a cleaning performance of the photoresist stripper composition, and may contribute to suppressing or reducing corrosion of a film made of metal such as aluminum in a rinse process, and to preventing or reducing damage to a metal oxide film.

The photoresist stripper composition including the polyhydric alcohol having 3 or less carbon atoms may have a risk of explosion under a special or certain condition. Accordingly, the polyhydric alcohol according to one or more embodiments may have 4 or more carbon atoms in a molecule. For example, the polyhydric alcohol may have 4 to 6 carbon atoms in a molecule. The polyhydric alcohol may be a linear alkyl alcohol having 4 to 6 carbon atoms. A terminology utilized in the present disclosure of “a linear alkyl group” refers to a straight-chained or branched alkyl group. For example, the linear alkyl alcohol may be composed in a manner in which at least three hydroxy groups are connected to a straight-chained alkyl group having 4 to 6 carbon atoms. The linear alkyl alcohol having 4 to 6 carbon atoms includes a racemic mixture, stereoisomer(s) thereof, and/or the like.

For example, the polyhydric alcohol may include at least one of erythritol, threitol, arabitol, xylitol, ribitol, mannitol, sorbitol, galactitol, fucitol, or iditol. A surface area of the polyhydric alcohol described above increases in a rinse process as a classification of the alcohol increases, so that intermolecular attraction thereof may increase. Accordingly, the photoresist stripper composition according to one or more embodiments including the polyhydric alcohol may exhibit improved cleaning performance. In one or more embodiments, the photoresist stripper composition according to one or more embodiments may include the polyhydric alcohol, and thus may stabilize an aluminum surface with Al₂O₃ in the rinse process, thereby exhibiting a more effective or suitable anti-corrosion performance.

In one or more embodiments, the polyhydric alcohol may have a content (e.g., amount) of about 0.05% to about 1% by weight with respect to the total weight of the photoresist stripper composition. When the polyhydric alcohol is included in the content (e.g., amount) range described above in the photoresist stripper composition, the photoresist pattern may be stripped without any (or substantially without any) surface damage for the lower film under the photoresist. When the content (e.g., amount) of the polyhydric alcohol is less than about 0.05% by weight, a cleaning performance and/or an anti-corrosion performance of the photoresist stripper composition may be deteriorated. In one or more embodiments, if (e.g., when) the content (e.g., amount) of the polyhydric alcohol is more than about 1% by weight, an insolubility phenomenon may occur, and thus the photoresist stripper composition itself may remain, and it may be difficult to completely clean a residue derived from the photoresist.

The photoresist stripper composition according to one or more embodiments of the present disclosure may not include (e.g., may exclude) water. For example, the photoresist stripper composition according to one or more embodiments may be a non-aqueous photoresist stripper composition. The water may include a deionized water (ultrapure water).

The photoresist stripper composition according to one or more embodiments may be utilized in a process of manufacturing an electronic device, for example, a process of removing the photoresist pattern in the process of manufacturing an electronic device. As an example, the photoresist stripper composition according to one or more embodiments may be utilized in a process of manufacturing an array substrate in a process of manufacturing a display device, and a process of removing the photoresist pattern formed on a metal film and/or a metal oxide film.

In one or more embodiments, the photoresist pattern may be removed through (e.g., via) a suitable stripper utilizing the photoresist stripper composition. Polyvinylbutyral may be applied as a glass adhesive in the stripper. When exposed to the photoresist stripper composition for a long time, such polyvinylbutyral may be dissolved and may fall, during the manufacturing process, on a substrate on which a lower film is formed. In this case, when the polyvinylbutyral has a greater specific gravity than the photoresist stripper composition, the polyvinylbutyral may be adsorbed on the substrate to be generated as a foreign matter (e.g., a foreign matter film).

To prevent or reduce the polyvinylbutyral from being generated as foreign matter, the photoresist stripper composition according to one or more embodiments of the present disclosure may have a greater specific gravity than the polyvinylbutyral. For example, the photoresist stripper composition according to one or more embodiments may include the protic polar organic solvent and the aprotic polar organic solvent described above, and thus may have a greater specific gravity than the polyvinylbutyral. For example, because the specific gravity of the polyvinylbutyral is about 1.00, the photoresist stripper composition according to one or more embodiments may have a specific gravity of about 1.01 or more. Accordingly, the photoresist stripper composition according to one or more embodiments may prevent or reduce the adsorption of polyvinylbutyral during the manufacturing process on the substrate on which the lower film is formed, and thus a risk of a product failure caused by the foreign matter may be reduced.

Hereinafter, a method for manufacturing an array substrate according to one or more embodiments of the present disclosure will be described with reference to the drawings. The method for manufacturing an array substrate may utilize the photoresist stripper composition according to one or more embodiments described above.

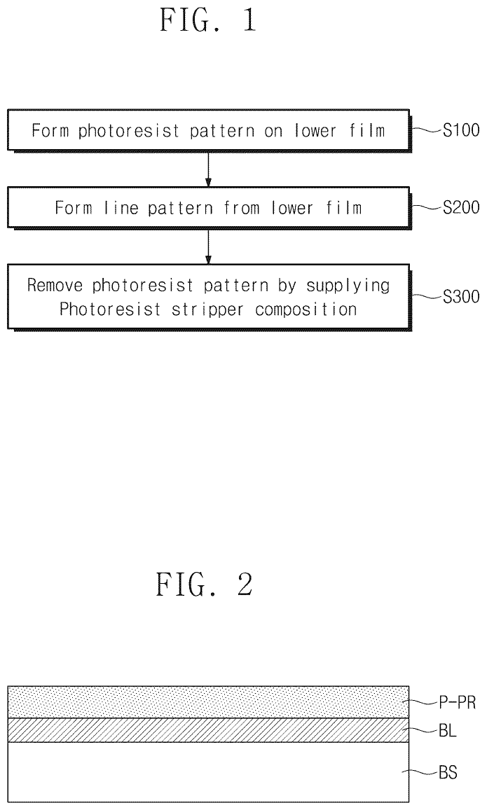

FIG. 1 is a flowchart schematically illustrating a method for forming (or providing) a pattern according to one or more embodiments. FIGS. 2 to 6 schematically illustrate the method for forming (or providing) a pattern according to one or more embodiments. Configurations illustrated in FIGS. 2 to 6 are illustrated enlarged, and may have sizes different from actual sizes thereof. Here, unless otherwise defined, the listing of operations, steps, tasks, or acts in a particular order should not necessarily means that the invention or claims require that particular order. That is, the general rule that unless the operations, steps, tasks, or acts of a method (e.g., a method claim) actually recite an order, the operations, steps, tasks, or acts should not be construed to require one.

Referring to FIG. 1, the method for forming (or providing) a pattern according to one or more embodiments may include an operation (or act) (S100) of forming (or providing) a photoresist pattern on a lower film, an operation (or act) (S200) of forming (or providing) a wiring pattern from the lower film, and an operation (or act) (S300) of removing the photoresist pattern by supplying a photoresist stripper composition.

Referring to FIGS. 1 and 2, a lower film BL may be formed on a substrate BS, and a photoresist film P-PR may be formed on the lower film BL. The substrate BS may be a member providing a base surface on which the lower film BL is arranged. The substrate BS may be a glass substrate, a metal substrate, a plastic substrate, and/or the like. However, one or more embodiments of the present disclosure are not limited thereto, and the substrate BS may be an inorganic layer, an organic layer, or a composite material layer (e.g., including an organic material and an inorganic material). In one or more embodiments, the substrate BS may include a semiconductor substrate such as a silicon wafer.

The lower film BL may include a metal film, a metal oxide film, and/or any suitable combination thereof. For example, the metal film may include metal such as aluminum (Al), copper (Cu), or an alloy thereof. The metal oxide film may be, for example, a silicon oxide film, a silicon nitride film, and/or the like, but one or more embodiments of the present disclosure are not limited thereto.

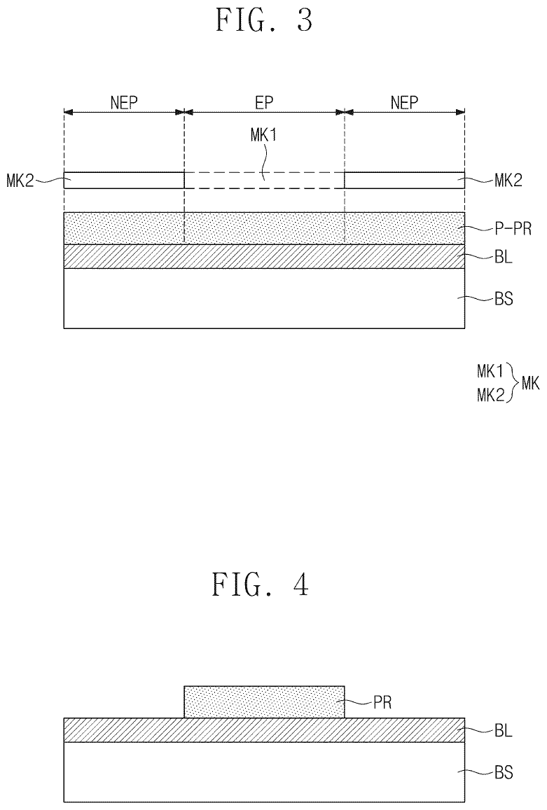

The photoresist film P-PR may be formed by applying and drying a photoresist composition on the lower film BL. In the present embodiments, a case in which a negative photoresist composition in which polymer curing is derived (e.g., occurs) in an exposure portion EP (see FIG. 3) is applied on the lower film BL is exemplarily described, but one or more embodiments of the present disclosure are not limited thereto. In some embodiments, a positive photoresist composition in which polymer softening occurs in the exposure portion EP (see FIG. 3) may be applied on the lower film BL to form (or provide) the photoresist film P-PR.

Referring to FIG. 3, an exposure process may be performed to the photoresist film P-PR utilizing a mask MK. The mask MK may be arranged to be spaced apart from the substrate BS on which the photoresist film P-PR is formed. The mask MK may include a transmission region MK1 and a blocking region MK2 to selectively transmit light (for example, UV light) incident from a top of the mask MK. Thereby, the exposure portion EP of the photoresist film P-PR overlapping the transmission region MK1 of the mask MK may be exposed to the light, for example, to be cross-linked/cured. In one or more embodiments, a non-exposure portion NEP of the photoresist film P-PR overlapping the blocking region MK2 may not be cured.

Referring to FIGS. 3 and 4 together, the non-exposure portion NEP of the photoresist film P-PR may be removed utilizing a developer. For example, the non-exposure portion NEP of the photoresist film P-PR not exposed to light due to the blocking region MK2 of the mask MK may be completely removed by the developer, so that a surface of the lower film BL may be exposed. In one or more embodiments, the photoresist film P-PR of the exposure portion EP may remain on the lower film BL to form (or provide) a photoresist pattern PR.

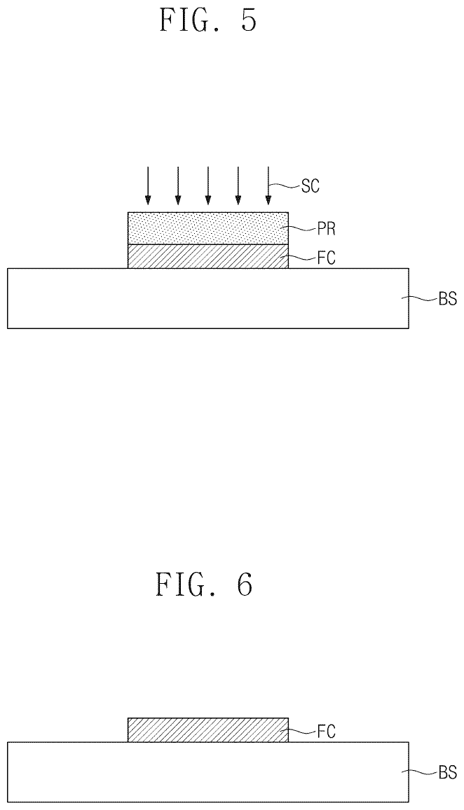

In one or more embodiments, the photoresist pattern PR may be utilized as an etching mask for patterning the lower film BL. For example, an etchant may be supplied on the lower film BL, and the lower film BL may be etched utilizing the supplied etchant. The lower film BL may not be etched in a region in which the photoresist pattern PR is arranged (due to the photoresist pattern PR), and may be etched in a region in which the photoresist pattern PR is not arranged, thereby forming (or providing) a wiring pattern FC as illustrated in FIG. 5. For example, the wiring pattern FC is formed from the lower film BL by an etching process. The etchant utilized in the etching process of the lower film BL is not limited to any one embodiment. Any suitable etchant may be applied to the present disclosure without any special limitation, as long as it is capable of suitably etching a film including a metal film, a metal oxide film, and/or any combination thereof.

Referring to FIGS. 5 and 6, the photoresist pattern PR on the wiring pattern FC may be removed by supplying the photoresist stripper composition SC according to one or more embodiments described above.

For example, stripping the photoresist pattern PR may be initiated by utilizing the photoresist stripper composition SC according to one or more embodiments. According to one or more embodiments, in the photoresist stripper composition SC including an amine compound, a cyclic alcohol, a protic polar organic solvent, an aprotic polar organic solvent, and a polyhydric alcohol, the amine compound may be in quick or suitable contact with the photoresist pattern PR without any (or substantially without any) damage due to evaporation, and removed photoresist ingredients may be quickly or suitably dissolved. Accordingly, the photoresist stripper composition SC according to one or more embodiments may dissolve the photoresist pattern PR by sufficiently or suitably swelling the photoresist pattern PR, and may remove the photoresist pattern PR from the substrate BS. Because the photoresist stripper composition SC described above has an improved photoresist dissolution ability, a strip process may be suitably performed by utilizing the photoresist stripper composition according to one or more embodiments, without substantially leaving a residue of the photoresist pattern PR on the wiring pattern FC and/or damaging the wiring pattern FC.

The method for forming (or providing) a pattern according to one or more embodiments may further include a rinse operation of cleaning the substrate BS on which the wiring pattern FC is formed after the operation of removing the photoresist pattern PR. The method for forming (or providing) a pattern according to one or more embodiments may not leave a residue (e.g., may leave substantially no residue) of the photoresist pattern PR on the wiring pattern FC through the rinse operation.

The wiring pattern FC formed by utilizing the photoresist stripper composition SC according to the present disclosure is not specially limited, and may be a single-layered film or a multi-layered film. The wiring pattern FC may be a line for a gate electrode, a source electrode, and/or a drain electrode constituting a thin-film transistor of a display device.

The photoresist stripper composition according to one or more embodiments of the present disclosure may remove the photoresist in a relatively short time by exhibiting an excellent or suitable strip ability for the photoresist without damaging (or substantially without damaging) the lower film including the metal film, the metal oxide film, and/or any suitable combination thereof. The photoresist stripper composition according to one or more embodiments has an excellent or suitable dissolution ability for the photoresist, thereby enabling improved economic efficiency through increase in a number of processed substrates, and has an excellent or suitable cleaning ability, thereby being capable of not leaving a residual solution and/or a surface impurity after stripping the photoresist pattern. Due to such effects, the photoresist stripper composition according to the present disclosure may contribute to yield increase in a process of manufacturing a semiconductor and a display device.

Hereinafter, a photoresist stripper composition according to one or more embodiments of the present disclosure and a line manufactured utilizing the same will be described with reference to Examples and Comparative Examples. However, Examples described below are provided for helping in understanding the present disclosure, and the scope of the present disclosure is not limited thereto.

### Examples

### 1. Manufacturing a Photoresist Stripper Composition and Evaluation of a Strip Performance of the Same.

Photoresist stripper compositions of Examples 1-1 and 1-2 according to one or more embodiments of the present disclosure and photoresist stripper compositions of Comparative Examples 1-1 to 1-8 were respectively manufactured according to compositions and contents described in Table 1. A unit indicating a content (e.g., amount) of each ingredient in Table 1 refers to a percent by weight with respect to 100% of the total weight of the photoresist stripper composition.

In one or more embodiments, an evaluation result of a strip performance for the photoresist stripper composition of Examples 1-1 and 1-2, and Comparative Examples 1-1 to 1-8 were represented in Table 1. In Table 1, a strip time (sec) represents a time taken to strip a photoresist pattern by supplying the photoresist stripper composition. For example, a photoresist was applied onto a substrate on which an aluminum (Al) metal film had been formed, and the substrate was heat-treated at a temperature of about 170° C. in an oven, so that a metal film line glass substrate on which the photoresist was not removed was manufactured. Removal times of cured and modified photoresists were measured by immersing the manufactured substrates in the photoresist stripper composition for the same length of time, while maintaining the manufactured photoresist stripper compositions at about 60° C.

Molecular weights and Hansen solubility parameters (HSPo) of the amine compounds utilized in Examples 1-1 and 1-2, and Comparative Examples 1-1 to 1-8 were represented in Table 2.

TABLE 1

| | | Example | Example | Comparative | Comparative | Comparative | Comparative |
|---|---|---|---|---|---|---|---|
| Ingredient | | 1-1 | 1-2 | Example 1-1 | Example 1-2 | Example 1-3 | Example 1-4 |
| Amine | MEA | | 10 | | | | |
| Compound | MIPA | 10 | | | | | |
| | AEE | | | 10 | | | |
| | AB | | | | 10 | | |
| | NMEA | | | | | 10 | |
| | HEP | | | | | | 10 |
| | DEA | | | | | | |
| | MDEA | | | | | | |
| | DEEA | | | | | | |
| | TEA | | | | | | |
| Cyclic alcohol | IPG | 10 | 10 | 10 | 10 | 10 | 10 |
| Aprotic polar | DMPA | 40 | 40 | 40 | 40 | 40 | 40 |
| organic solvent | | | | | | | |
| Protic polar | EDG | 39.9 | 39.9 | 39.9 | 39.9 | 39.9 | 39.9 |
| organic solvent | | | | | | | |
| Polyhydric alcohol | SBT | 0.1 | 0.1 | 0.1 | 0.1 | 0.1 | 0.1 |
| Specific Gravity | — | 1.02 | 1.02 | 1.01 | 1.01 | 1.02 | 1.02 |
| Strip time (sec) | — | 25 | 20 | 30 | 40 | 30 | 70 |

| | | Comparative | Comparative | Comparative | Comparative |
|---|---|---|---|---|---|
| Ingredient | | Example 1-5 | Example 1-6 | Example 1-7 | Example 1-8 |
| Amine | MEA | | | | |
| Compound | MIPA | | | | |
| | AEE | | | | |
| | AB | | | | |
| | NMEA | | | | |
| | HEP | | | | |
| | DEA | 10 | | | |
| | MDEA | | 10 | | |
| | DEEA | | | 10 | |
| | TEA | | | | 10 |
| Cyclic alcohol | IPG | 10 | 10 | 10 | 10 |
| Aprotic polar | DMPA | 40 | 40 | 40 | 40 |
| organic solvent | | | | | |
| Protic polar | EDG | 39.9 | 39.9 | 39.9 | 39.9 |
| organic solvent | | | | | |
| Polyhydric alcohol | SBT | 0.1 | 0.1 | 0.1 | 0.1 |
| Specific Gravity | — | 1.03 | 1.02 | 1.00 | 1.01 |
| Strip time (sec) | — | 60 | 130 | 120 | 150 |

AEE: 2-(2-aminoethoxy)ethanol)
AB: 2-amino-1-butanol
MIPA: monoisopropanolamine
MEA: monoethanolamine
NMEA: N-methylethanolamine
HEP: 1-(2-hydroxyethyl)-piperazine
DEA: diethanolamine
MDEA: methyldiethanolamine
DEEA: 2-diethyamino-ethanol
TEA: triethanolamine
IPG: 1,2-isopropylideneglycerol
EDG: diethyleneglycolmonoethylether
DMPA: N,N-dimethylpropionamide
SBT: sorbitol

TABLE 2

| | | |
|---|---|---|
| Amine | Molecular | Hansen solubility parameter |

| compound | weight (MW) | HSPo | HSPd | HSPp | HSPh |
|---|---|---|---|---|---|
| AEE | 105.14 | 26.6 | 16.2 | 9.4 | 18.9 |
| AB | 89.14 | 24.1 | 16.9 | 7.6 | 15.4 |
| MIPA | 75.11 | 27.8 | 15.8 | 9.4 | 20.9 |
| MEA | 61.08 | 31.3 | 17.0 | 15.5 | 21.2 |
| NMEA | 75.11 | 24.7 | 16.1 | 12.3 | 14.1 |
| HEP | 130.19 | 25.1 | 16.9 | 11.4 | 14.6 |
| DEA | 105.14 | 29.4 | 17.2 | 10.8 | 21.2 |
| MDEA | 119.16 | 28.3 | 16.9 | 11.1 | 19.8 |
| DEEA | 117.18 | 20.6 | 15.7 | 5.8 | 12.0 |
| TEA | 149.19 | 28.2 | 17.3 | 7.6 | 21.0 |

Referring to Tables 1 and 2, it may be seen that the photoresist stripper compositions according to Examples utilizing the amine compound having a molecular weight of about 80 g/mol or less, and a Hansen solubility parameter (HSPo) according to Equation 1 of about 27 to 32 are each capable of removing the photoresist pattern in a shorter amount of time compared to the photoresist stripper compositions according to Comparative Examples.

For example, it may be confirmed that the photoresist patterns of Examples 1-1 and 1-2 were each stripped within about 30 seconds (e.g., in less than 30 seconds). Accordingly, the photoresist stripper compositions according to Examples showed an excellent or suitable performance in removing the photoresist pattern. In addition, it may be confirmed from the evaluation result of the strip time according to each of Examples 1-1 and 1-2 that the smaller the molecular weight, the shorter the strip time, and that the greater the Hansen solubility parameter (HSPo), the shorter the strip time.

It may be seen that the photoresist stripper compositions according to Comparative Examples 1-1, 1-2, 1-4, and 1-7 including the amine compounds having Hansen solubility parameters (HSPo) of less than about 27, and molecular weights of more than about 80 g/mol have longer strip times compared to those according to Examples.

In addition, it may be seen that because the amine compound included in the photoresist stripper composition according to Comparative Example 1-3 has a molecular weight of about 80 g/mol or less, but has a HSPo of less than about 27, the photoresist stripper composition according to Comparative Example 1-3 has a longer strip time compared to those according to Examples.

It may be seen that because the amine compounds included in the photoresist stripper compositions according to Comparative Examples 1-5, 1-6, and 1-8 have a HSPo of about 27 to about 32, but a molecular weight of more than about 80 g/mol, the photoresist stripper compositions according to Comparative Examples 1-5, 1-6, and 1-8 have longer strip times compared to those according to Examples.

When utilizing the photoresist stripper composition according to the present embodiments, as compared to the compositions utilized in Comparative Examples 1-1 to 1-8, it may be confirmed that the smaller the molecular weight of the amine compound, the shorter the strip time, and the greater HSPo of the amine compound, the shorter the strip time.

### 2. Manufacturing a Photoresist Stripper Composition and Evaluation of an Anti-Corrosion Performance of the Same.

Photoresist stripper compositions of Examples 2-1 to 2-6 according to one or more embodiments of the present disclosure and photoresist stripper compositions of Comparative Examples 2-1 to 2-8 were respectively manufactured according to compositions and contents described in Tables 3 and 4. A unit indicating a content (e.g., amount) of each ingredient in Tables 3 and 4 represents a percent by weight with respect to 100% of the total weight of the photoresist stripper composition.

In one or more embodiments, evaluation results of anti-corrosion performances of the photoresist stripper compositions of Examples 2-1 to 2-6 were described in Table 3, and evaluation results of the anti-corrosion performances of the photoresist stripper compositions of Comparative Examples 2-1 to 2-8 were described in Table 4. Evaluation of the anti-corrosion performances in Tables 3 and 4 were made by relatively comparing corrosion levels of aluminum metal lines after immersing, for about 300 seconds, substrates on which the aluminum metal lines had been formed and photoresist had been removed, in the photoresist stripper composition according to Examples and Comparative Examples. Evaluation criteria of the anti-corrosion performance are as follows:

### Evaluation Criteria

⊚: No change in a surface of the metal film is observed.
Δ: A detectable (e.g., small) change in a surface of the metal film is observed.
X: An apparent (e.g., substantial) change in a surface of the metal film is observed.

TABLE 3

| | | Example | Example | Example | Example | Example | Example |
|---|---|---|---|---|---|---|---|
| Ingredient | | 2-1 | 2-2 | 2-3 | 2-4 | 2-5 | 2-6 |
| Amine | MEA | 5 | 10 | 15 | | | |
| compound | MIPA | | | | 5 | 10 | 15 |
| Cyclic alcohol | IPG | 10 | 10 | 10 | 10 | 10 | 10 |
| Aprotic polar | DMPA | 40 | 40 | 40 | 40 | 40 | 40 |
| organic solvent | | | | | | | |
| Protic polar | EDG | 44.95 | 39.95 | 34.95 | 44.95 | 39.95 | 34.95 |
| organic solvent | | | | | | | |
| Polyhydric | XLT | 0.05 | 0.05 | | | | |
| alcohol | SBT | | | 0.05 | 0.05 | | |
| | IDT | | | | | 0.05 | 0.05 |
| | VLT | | | | | | |
| | LTT | | | | | | |

| | | | | | | |
|---|---|---|---|---|---|---|
| Evaluation result of anti- | ⊚ | ⊚ | ⊚ | ⊚ | ⊚ | ⊚ |
| corrosion performance | | | | | | |

MIPA: monoisopropanolamine
MEA: monoethanolamine
IPG: 1,2-isopropylideneglycerol
EDG: diethyleneglycolmonoethylether
DMPA: N,N-dimethylpropionamide
XLT: xylitol
SBT: sorbitol
IDT: iditol
VLT: volemitol
LTT: lactitol

TABLE 4

| | | Comparative | Comparative | Comparative | Comparative | Comparative | Comparative | Comparative | Comparative |
|---|---|---|---|---|---|---|---|---|---|
| Ingredient | | Example 2-1 | Example 2-2 | Example 2-3 | Example 2-4 | Example 2-5 | Example 2-6 | Example 2-7 | Example 2-8 |
| Amine | MEA | 15 | 17 | 15 | 15 | | | | |
| Compound | MIPA | | | | | 15 | 17 | 15 | 4 |
| Cyclic alcohol | IPG | 10 | 10 | 10 | 17 | 10 | 10 | 10 | 10 |
| Aprotic polar | DMPA | 40 | 40 | 40 | 40 | 40 | 40 | 40 | 40 |
| organic solvent | | | | | | | | | |
| Protic polar | EDG | 35 | 32.95 | 34.97 | 27.95 | 35 | 32.95 | 34.97 | 45.95 |
| organic solvent | | | | | | | | | |
| Polyhydric | XLT | | 0.05 | 0.03 | | | | | |
| alcohol | SBT | | | | 0.05 | | 0.05 | | |
| | IDT | | | | | | | 0.03 | 0.05 |
| | VLT | 0.05 | | | | | | | |
| | LTT | | | | | 0.05 | | | |

| | | | | | | | | |
|---|---|---|---|---|---|---|---|---|
| Evaluation result of anti- | Δ | X | X | Δ | X | X | X | unstripped |
| corrosion performance | | | | | | | | |

MIPA: monoisopropanolamine
MEA: monoethanolamine
IPG: 1,2-isopropylideneglycerol
EDG: diethyleneglycolmonoethylether
DMPA: N,N-dimethylpropionamide
XLT: xylitol
SBT: sorbitol
IDT: iditol
VLT: volemitol
LTT: lactitol

Referring to Tables 3 and 4, it may be seen that the photoresist stripper compositions according to Examples do not substantially cause corrosion of the aluminum lines, compared to the photoresist stripper compositions according to Comparative Examples. For example, it may be seen that the photoresist stripper compositions according to Examples each have excellent or suitable anti-corrosion characteristics for the lower film.

For example, it may be confirmed through the results of Comparative Examples 2-1 and 2-5, that when a number of carbon atoms of the polyhydric alcohol exceeds 6, the anti-corrosion performance is deteriorated. In addition, it may be confirmed through the results of Comparative Examples 2-3 and 2-7, that when a content (e.g., amount) of the polyhydric alcohol is less than about 0.05% by weight, the anti-corrosion performance is deteriorated.

It may be confirmed through Comparative Examples 2-2 and 2-6, that when a content (e.g., amount) of the amine compound exceeds about 15%, the anti-corrosion performance is deteriorated. In one or more embodiments, it may be confirmed through Comparative Example 2-8, that when the content (e.g., amount) of the amine compound is less than about 5% by weight, the photoresist is not suitably stripped so that the photoresist stripper composition is not appropriate or suitable to utilize irrespective of the anti-corrosion performance thereof.

In addition, it may be confirmed through Comparative Example 2-4, that when a content (e.g., amount) of the cyclic alcohol exceeds about 15% by weight, the anti-corrosion performance is deteriorated.

### 3. Evaluation of an Anti-Corrosion Performance 2

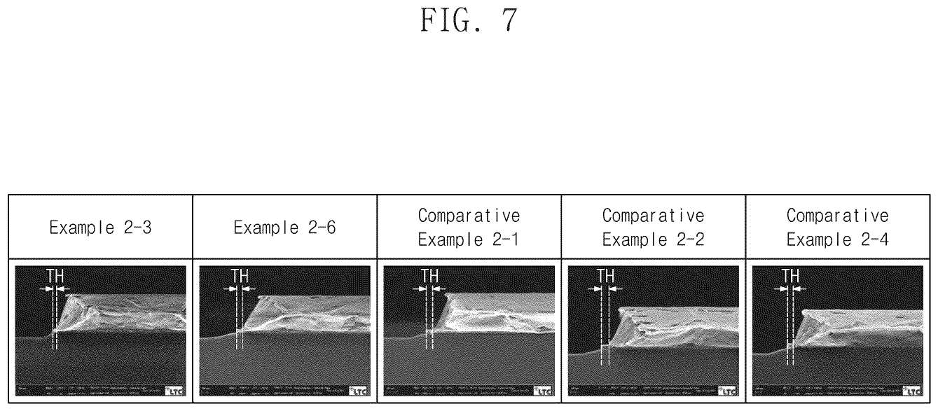

Anti-corrosion performances of the photoresist stripper compositions of Examples 2-3 and 2-6, and Comparative Examples 2-1, 2-2, and 2-4 were further evaluated and confirmed. Here, edge thicknesses of the aluminum metal lines were measured through FE-SEM for the substrates utilized in the evaluation of an anti-corrosion performance. The results were represented in Table 5 and FIG. 7.

TABLE 5

| Evaluation | | | | | |
|---|---|---|---|---|---|
| results | | | | | |
| of anti- | | | Compar- | Compar- | Compar- |
| corrosion | | | ative | ative | ative |
| perfor- | Example | Example | Example | Example | Example |
| mances | 2-3 | 2-6 | 2-1 | 2-2 | 2-4 |
| Thickness | 73.24 nm | 79.1 nm | 108.4 nm | 128.9 nm | 102.5 nm |
| (TH) | | | | | |

Referring to Table 5 and FIG. 7, it may be seen that the photoresist stripper compositions of Examples 2-3 and 2-6 have excellent or suitable anti-corrosion performances, compared to the photoresist stripper compositions of Comparative Examples 2-1, 2-2 and 2-4.

For example, it may be confirmed that Examples 2-3 and 2-6 have remarkably small edge thicknesses, compared to Comparative Examples. Accordingly, it may be seen that the photoresist stripper compositions of Examples exhibit excellent or suitable anti-corrosion performances.

A photoresist stripper composition according to one or more embodiments may exhibit an excellent or suitable strip ability for photoresist without any (or substantially without any) damage to a lower film, thereby removing the photoresist in a relatively short amount of time. In addition, the photoresist stripper composition according to one or more embodiments has excellent or suitable dissolution ability and cleaning ability for the photoresist, so that a residual solution and/or a surface impurity may not be left (e.g., may substantially not be left) after stripping the photoresist.

When the photoresist stripper composition described above in a method for forming (or providing) a pattern according to one or more embodiments is utilized, a strip rate and a strip efficiency may be improved.

In the present disclosure, description has been made with reference to embodiments of the present disclosure, but those skilled in the art and/or those of ordinary skill in the relevant technical field may understand that one or more suitable modifications and changes may be made to the present disclosure within the scope thereof, without departing from the spirit and the technology scope of the present disclosure as described in the claims provided hereinbelow.

The patterning device and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Therefore, the technical scope of the present disclosure is not limited to the contents described in the detailed description of the specification, but should be determined by the claims and their equivalents.

What is claimed is:

1. A photoresist stripper composition comprising:
with respect to a total weight of the photoresist stripper composition,
about 5% to about 15% by weight of an amine compound having a molecular weight of about 80 g/mol or less, and a Hansen solubility parameter (HSPo) according to Equation 1 of about 27 to about 32;
about 5% to about 15% by weight of a cyclic alcohol;
about 10% to about 55% by weight of a protic polar organic solvent;
about 10% to about 55% by weight of an aprotic polar organic solvent; and
about 0.05% to about 1% by weight of a polyhydric alcohol having 4 to 6 carbon atoms:
$$HSPo = {( {HSPd}^{2} + {HSPp}^{2} + {HSPh}^{2} )}^{0.5} , \qquad Equation l$$
wherein in Equation 1,
HSPd is a solubility parameter generated by non-polar dispersive bonding, HSPp is a solubility parameter generated by polar bonding caused by permanent dipoles, and HSPh is a solubility parameter generated by hydrogen bonding.

2. The photoresist stripper composition of claim 1, wherein the amine compound is an alkanol amine compound.

3. The photoresist stripper composition of claim 1, wherein the amine compound comprises at least one of monoisopropanolamine, 3-amino-1-propanol, monoethanolamine, or 2-methylaminoethanol.

4. The photoresist stripper composition of claim 1, wherein the amine compound is a primary amine compound.

5. The photoresist stripper composition of claim 1, wherein the cyclic alcohol has 4 to 6 carbon atoms in a molecule.

6. The photoresist stripper composition of claim 1, wherein the cyclic alcohol comprises at least one of tetrahydrofurfuryl alcohol, furfuryl alcohol, cyclobutanol, cyclopentanol, cyclohexanol, or isopropylideneglycerol.

7. The photoresist stripper composition of claim 1, wherein the protic polar organic solvent comprises a glycol-based compound represented by Formula 1 or Formula 2: 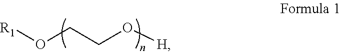
in Formula 1, R₁ is a hydrogen atom, a substituted or unsubstituted alkyl group having 1 to 10 carbon atoms, a substituted or unsubstituted cycloalkyl group having 3 to 15 ring-forming carbon atoms, or a substituted or unsubstituted aryl group having 3 to 15 ring-forming carbon atoms, and
n is an integer of 1 or more: 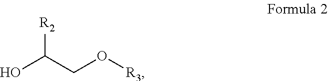
and
in Formula 2, R₂ is a hydrogen atom, or a substituted or unsubstituted alkyl group having 1 to 10 carbon atoms, and
R₃ is a hydrogen atom, a substituted or unsubstituted alkyl group having 1 to 10 carbon atoms, or a substituted or unsubstituted alkoxy group having 1 to 10 carbon atoms.

8. The photoresist stripper composition of claim 1, wherein the protic polar organic solvent comprises at least one of ethyleneglycol, propyleneglycol, diethyleneglycolmonoethylether, diethyleneglycolmonobutylether, diethyleneglycolmonomethylether, ethyleneglycolmonoethylether, ethyleneglycolmonobutylether, propyleneglycolmonomethylether, propyleneglycolmonoethylether, propyleneglycolmonobutylether, diethyleneglycolmonoethylether, diethyleneglycolmonopropylether, diethyleneglycolmonobutylether, dipropyleneglycolmonomethylether, dipropyleneglycolmonoethylether, dipropyleneglycolmonopropylether, dipropyleneglycolmonobutylether, triethyleneglycolmonopropylether, triethyleneglycolmonobutylether, triethyleneglycolmonomethylether, tripropyleneglycolmonoethylether, tripropyleneglycolmonopropylether, or tripropyleneglycolmonobutylether.

9. The photoresist stripper composition of claim 1, wherein the photoresist stripper composition does not comprise N-methyl-2-pyrrolidone and does not comprise N-methylformamide.

10. The photoresist stripper composition of claim 1, wherein the aprotic polar organic solvent comprises at least one of 2-pyrrolidone, 4-formylmorpholine, N,N-dimethylpropionamide, 1,3-dimethyl-2-imidazolidinone, N,N-dimethylacetoacetamide, sulfolane, N-ethylformamide, or equamide.

11. The photoresist stripper composition of claim 1, wherein the polyhydric alcohol is a linear alkyl alcohol.

12. The photoresist stripper composition of claim 1, wherein the polyhydric alcohol comprises at least one of erythritol, threitol, arabitol, xylitol, ribitol, mannitol, sorbitol, galactitol, fucitol, or iditol.

13. The photoresist stripper composition of claim 1, wherein the photoresist stripper composition does not comprise water.

14. The photoresist stripper composition of claim 1, wherein the photoresist stripper composition has a specific gravity of about 1.01 or more.

15. A method for forming a pattern, the method comprising:
applying a photoresist pattern on a substrate on which a lower film is provided;
applying a wiring pattern utilizing the photoresist pattern; and
removing the photoresist pattern by a photoresist stripper composition,
wherein the photoresist stripper composition comprises, with respect to a total weight of the photoresist stripper composition,
about 5% to about 15% by weight of an amine compound having a molecular weight of about 80 g/mol or less, and a Hansen solubility parameter (HSPo) according to Equation 1 of about 27 to about 32,
about 5% to about 15% by weight of a cyclic alcohol,
about 10% to about 55% by weight of a protic polar organic solvent,
about 10% to about 55% by weight of an aprotic polar organic solvent, and
about 0.05% to about 1% by weight of polyhydric alcohol having 4 to 6 carbon atoms:
$$HSPo = {( {HSPd}^{2} + {HSPp}^{2} + {HSPh}^{2} )}^{0.5} , \qquad Equation l$$
and
wherein in Equation 1,
HSPd is a solubility parameter generated by non-polar dispersive bonding, HSPp is a solubility parameter generated by polar bonding caused by permanent dipoles, and HSPh is a solubility parameter generated by hydrogen bonding.

16. The method of claim 15, wherein the lower film comprises:
a metal film selected from among aluminum (Al), copper (Cu), and an alloy thereof;
a metal oxide film selected from among a silicon oxide film and a silicon nitride film; or
any combination thereof.

17. The method of claim 15, wherein the lower film is a single-layered film or a multi-layered film.

18. The method of claim 15, wherein the amine compound is an alkanol amine compound.

19. The method of claim 15, wherein the amine compound is selected from among monoethanolamine and monoisopropanolamine.

20. The method of claim 15, wherein the polyhydric alcohol is selected from among xylitol, sorbitol, and iditol.
